(19) United States
(12) Patent Application Publication
(10) Pub. No.: US 2024/0375942 A1
(43) Pub. Date: Nov. 14, 2024

(54) DOUBLE NOTCH ETCH TO REDUCE UNDER CUT OF MICRO ELECTRO-MECHANICAL SYSTEM (MEMS) DEVICES

(71) Applicant: CALIENT TECHNOLOGIES, INC., Goleta, CA (US)

(72) Inventor: Paul WALDROP, Ithaca, NY (US)

(73) Assignee: CALIENT TECHNOLOGIES, INC., Goleta, CA (US)

(21) Appl. No.: 18/656,629

(22) Filed: May 7, 2024

Related U.S. Application Data
(60) Provisional application No. 63/500,981, filed on May 9, 2023.

(51) Int. Cl. B81C 1/00

(52) U.S. Cl. CPC B81C 1/00571; B81C 2201/014; B81C 2201/0176; B81C 2201/0198; B81C 2201/056

(57) ABSTRACT

Disclosed are methods and devices relating to microelectromechanical systems (MEMS). A method for fabricating a mechanical beam in a microelectromechanical (MEM) device may comprise depositing a masking layer on a first side of a substrate; etching a first notch on the first side of the substrate; forming a beam structure on the substrate, wherein a first portion of the beam structure is coupled to the first notch; etching a second notch at a second portion of the beam structure; depositing an oxide layer on the beam structure, the masking layer, and the substrate; etching a horizontal surface of the oxide layer at the masking layer and the substrate; and releasing the mechanical beam from the substrate, wherein the mechanical beam comprises the beam structure, the oxide layer, and the masking layer.

### CROSS-REFERENCE

This application claims the benefit of U.S. Provisional Application No. 63/500,981, filed May 9, 2023, entitled DOUBLE NOTCH ETCH TO REDUCE UNDER CUT OF MICRO-ELECTROMECHANICAL SYSTEMS (MEMS) DEVICES which application is incorporated herein in its entirety by reference.

### BACKGROUND

MEMS (micro electro-mechanical system) devices may be micro-sized mechanical structures and may be fabricated using various integrated circuit (IC) fabrication methods. For example, MEMS devices may include a MEMS micro mirror device which may include one or more mechanical beam structures (also referred to as flexures) for suspending a reflective surface. Methods for manufacturing MEMS micro mirror devices with reduced variability would be useful.

### SUMMARY

Disclosed are mechanical beams associated with micro-electromechanical systems (MEMS) devices and methods of manufacturing or fabricating the mechanical beams associated with the MEMS devices.

A microelectromechanical (MEM) device may include a substrate and a mechanical beam. The mechanical beam may include a beam structure on a first side of the substrate. The first portion of the beam structure may include a first notch and a second portion of the beam structure may include a second notch. The mechanical beam may include a masking layer positioned on a horizontal surface of the beam structure. The mechanical beam may include an oxide layer positioned on a vertical surface of the beam structure.

A method for reducing variability of a mechanical beam in a microelectromechanical (MEM) device may include forming a beam structure on a substrate. The beam structure may include: a first notch at a first portion of the beam structure, a second notch at a second portion of the beam structure, and a body positioned between the first notch and the second notch. The method may include releasing the beam structure from the substrate using an etching process that facilitates reduced variability of one or more of: a mechanical stiffness of the mechanical beam, a height of the mechanical beam, or a performance characteristic of the mechanical beam. The variability may be compared to a baseline variability without the second notch.

A method for fabricating a mechanical beam in a microelectromechanical (MEM) device may include depositing a masking layer on a first side of a substrate; etching a first notch on the first side of the substrate; forming a beam structure on the substrate in which a first portion of the beam structure is coupled to the first notch; etching a second notch at a second portion of the beam structure; depositing an oxide layer on the beam structure, the masking layer, and the substrate; etching a horizontal surface of the oxide layer at the masking layer and the substrate; and releasing the mechanical beam from the substrate in which the mechanical beam may include the beam structure, the oxide layer, and the masking layer.

Both the foregoing general description and the following detailed description are exemplary and explanatory only and are not restrictive of the disclosed implementations, as claimed.

### INCORPORATION BY REFERENCE

All publications, patents, and patent applications mentioned in this specification are herein incorporated by reference to the same extent as if each individual publication, patent, or patent application was specifically and individually indicated to be incorporated by reference.
U.S. Pat. No. 4,685,198 issued Aug. 11, 1987 to Kawakita et al.;
U.S. Pat. No. 5,198,390 issued Mar. 30, 1993 to MacDonald;
U.S. Pat. No. 5,316,979 issued May 31, 1994 to MacDonald;
U.S. Pat. No. 5,426,070 issued Jun. 20, 1995 to Shaw et al.;
U.S. Pat. No. 5,501,893 issued Mar. 26, 1996 to Laermer et al.;
U.S. Pat. No. 5,880,035 issued Mar. 9, 1999 to Fukuda;
U.S. Pat. No. 6,174,784 issued Jan. 16, 2001 to Forbes;
U.S. Pat. No. 6,306,715 issued Oct. 23, 2001 to Chan et al.;
U.S. Pat. No. 6,712,983 issued Mar. 30, 2004 to Zhao et al.;
U.S. Pat. No. 7,214,625 issued May 8, 2007 to Asami et al.;
U.S. Pat. No. 7,524,767 issued Apr. 28, 2009 to Chilcott;
U.S. Pat. No. 7,947,576 issued May 24, 2011 to Igari et al.;
U.S. Pat. No. 8,198,148 issued Jun. 12, 2012 to Koo et al.;
U.S. Pat. No. 8,853,803 issued Oct. 7, 2014 to Adams et al.;
U.S. Pat. No. 9,773,677 issued Sep. 26, 2017 to Surthi;
U.S. Pat. No. 11,107,812 issued Aug. 31, 2021 to Chan et al.; and
US 2015/0206761 A1 published Jul. 23, 2015 to Fucsko et al.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIGS. 1A-1E illustrate in diagrammatic cross-section the fabrication of a mechanical beam from a silicon wafer in accordance with the disclosure;

FIGS. 2A-2B illustrate a flowchart of an example arrangement of operations for a method of generating and/or producing a mechanical beam in accordance with the disclosure;

FIG. 3 illustrates a flowchart of an example arrangement of operations for a method of generating and/or producing a mechanical beam in accordance with the disclosure;

FIGS. 4A-B illustrate a cross-section of a second mechanical beam including a second beam structure without the second notch released from the silicon substrate in accordance with the disclosure; and

FIG. 5 illustrates a first mechanical beam structure including the second notch in accordance with the disclosure.

### DETAILED DESCRIPTION

In a general process, the top of a silicon mechanical beam may be defined by a photolithography resist layer on silicon dioxide. The silicon dioxide layer may be chemically etched (dry or wet). The silicon substrate may be etched using deep reactive ion etching (DRIE), for example. Using DRIE takes advantage of the fact that the Bosch deep silicon etch process uses alternating etch and deposition cycles as described in U.S. Pat. No. 5,501,893.

After a deep silicon etch, several operations may be performed including (i) a thin sidewall passivation deposition (usually using silicon dioxide), (ii) an anisotropic oxide etch to clear the passivation from the floor of the cavity, (iii) a second anisotropic etch, and (iv) an isotropic silicon etch to release the mechanical structure. The isotropic silicon etch to release the mechanical structure may cause a significant amount of undercutting of the silicon core of the structural members. As a result, the mechanical stiffness of the structure may decrease with the increased undercut. Additionally, the undercut may add variability to the stiffness of the structure because the actual height of the mechanical structure is not certain. Consequently, the mechanical structure may be more difficult to model.

Disclosed are mechanical beams associated with micro-electromechanical systems (MEMS) devices and methods of manufacturing or fabricating the mechanical beams associated with the MEMS devices. Also disclosed are processes to reduce the stiffness variability of the mechanical structure during the manufacturing process. The mechanical structures disclosed may have a predictable height which may be modeled. By reducing the amount of an undercut of a silicon structure, the dimensions of the mechanical beams may be better controlled. Consequently, the mechanical behavior of the manufactured beams may be closer to the mechanical behavior of the modelled beams prior to manufacture. Because the mechanical behavior of the modelled beams and manufactured beams may be closer, the performance of the device may have less variability.

A method for fabricating a mechanical beam in a microelectromechanical (MEM) device may include depositing a masking layer on a first side of a substrate; etching a first notch on the first side of the substrate; forming a beam structure on the substrate in which a first portion of the beam structure is coupled to the first notch; etching a second notch at a second portion of the beam structure; depositing an oxide layer on the beam structure, the masking layer, and the substrate; etching a horizontal surface of the oxide layer at the masking layer and the substrate; and releasing the mechanical beam from the substrate in which the mechanical beam may include the beam structure, the oxide layer, and the masking layer.

The method may be effectuated as described. At the beginning of the etch process, a relatively aggressive silicon etch operation may be performed to form a first notch. The first notch may allow a subsequent conformal sidewall passivation coating to better protect the top corner edges of the silicon beam during the isotropic release etch. After the formation of the first notch, the silicon etch process may continue with alternating cycles of deposition and etching to produce a vertical etch profile matching the width of the mask oxide.

When the etch approaches a desired depth into the silicon, a second relatively aggressive etch operation may be performed. Following the second etch operation, the deep silicon etching ends. A thin, conformal sidewall passivation film may be deposited on the structure. The passivation film may be, for example a plasma-enhanced chemical vapor deposition (PECVD) silicon dioxide coating. When the coating has been applied, an anisotropic etch may be performed to remove the passivation coating from the horizontal surface to leave the coating intact on the vertical surfaces.

An isotropic release etch may be performed. The isotropic release etch may be, for example, an SF6 or XeF6 etch. Because the bottom of the mechanical beam may be pinched off, the amount of undercut into the silicon core of the mechanical beam may be reduced.

The mechanical beam may be more accurately modelled, and the height of the mirrors of the MEMS may have an increased uniformity which may increase yield. Currently, the variation in structural height from a target structural height may be as much as 50%. The disclosed process, however, allows structural height variation to be reduced to less than one or more of 20%, 10%, 5%, or the like from the target structural height.

### I. Methods of Manufacture

A method of releasing a mechanical structure from a silicon substrate may include: (i) a deep silicon etch, (ii) a thin sidewall passivation deposition (e.g., using plasma-enhanced chemical vapor deposition (PECVD) silicon dioxide coating), (iii) an anisotropic oxide etch to clear the passivation from the floor of the cavity, (iv) a second anisotropic etch, and (v) an isotropic etch to release the mechanical structure from the silicon substrate. When releasing the mechanical structure from the silicon substrate using the isotropic etch, undercutting of the mechanical structure may occur. Therefore, methods that facilitate a reduced undercut may be useful.

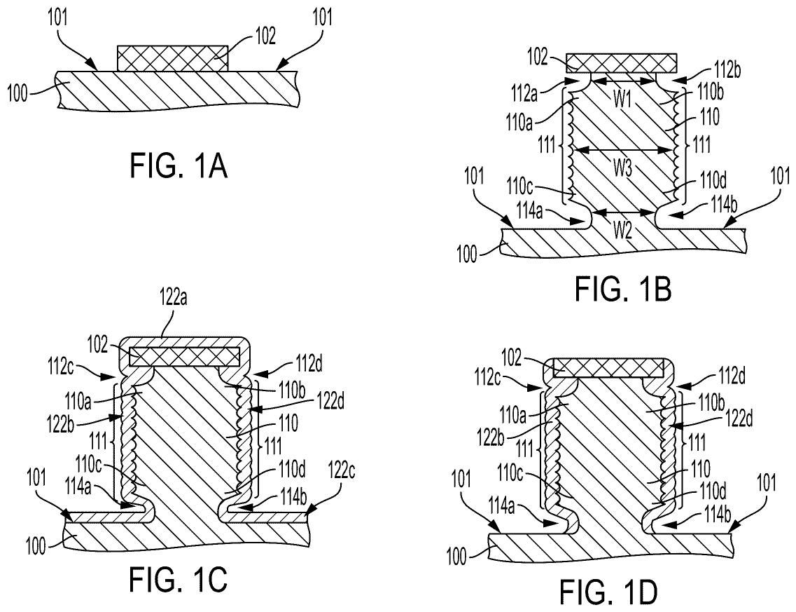

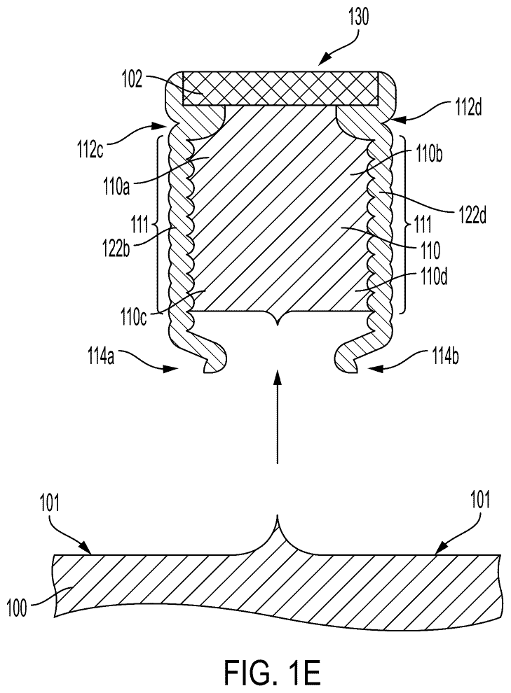

As illustrated in the cross-section of a microelectromechanical (MEM) device during fabrication shown in FIGS. 1A-1E, the method for fabricating the MEM device may include: depositing a masking layer (e.g., an oxide mask 102 such as a silicon oxide mask) on a first side 101 of a substrate (e.g., a silicon substrate 100 such as a silicon wafer). The method may include etching a first notch 112a, 112b on the first side 101 of the substrate. The method may include forming a beam structure 110 on the substrate (e.g., the silicon substrate 100 such as a silicon wafer). A first portion (e.g., an upper portion) of the beam structure 110 may be coupled to the first notch 112a, 112b. The cross-section of the beam structure 110 may have top corner edges 110a, 110b and bottom corner edges 110c, 110d. The method may include etching a second notch 114a, 114b at a second portion (e.g., a lower portion) of the beam structure 110. Additionally, an oxide layer 122a, 122b, 122c, 122d can be deposited on the beam structure 110, the masking layer (e.g., an oxide mask 102 such as a silicon oxide mask), and the substrate (e.g., a silicon substrate 100 such as a silicon wafer). A horizontal surface of the oxide layer 122a, 122c can be etched at the masking layer (e.g., an oxide mask 102 such as a silicon oxide mask) and the substrate (e.g., a silicon substrate 100 such as a silicon wafer). Additionally, the method may include releasing the mechanical beam 130 from the substrate (e.g., a silicon substrate 100 such as a silicon wafer). The mechanical beam may include the beam structure 110, the oxide layer 122b, 122d, and the masking layer (e.g., an oxide mask 102 such as a silicon oxide mask). The oxide layer 122a, 122b, 122c, 122d may be a silicon dioxide layer.

One or more of the first notch 112a, 112b or the second notch 114a, 114b may be etched by increasing an etching time compared to a body etching time for a body 111 of the beam structure 110. The longer etch time, the deeper and higher the notch.

Turning now to FIG. 1A, an oxide mask 102 (e.g., silicon oxide mask) grown on a first side 101 of a silicon substrate 100 (e.g., silicon wafer) is illustrated. The oxide layer (e.g., silicon oxide layer) may be formed on the first side 101 of the silicon substrate 100 using an oxidation process such as a thermal oxidation process. For example, a process that involves exposing the silicon substrate 100 to oxygen gas (02) and/or H₂O gas (wet oxide) at a high temperature (e.g., a temperature range between 800° C. and 1200° C. such as 900° C.) may be used to form an oxide layer on the surface (e.g., a first side 101) of the silicon substrate 100. The thickness of the oxide layer may depend on the time and temperature of the oxidation process.

After forming the oxide layer on the first side 101 of the silicon substrate 100, a layer of photoresist may be applied to the surface of the oxide layer using spin coating or other suitable techniques. The photoresist layer on the oxide layer may be exposed to light (e.g., ultraviolet light) through a patterned mask or reticle, which selectively exposes certain areas of the photoresist layer. The exposed areas of the photoresist layer may be removed using a developer solution, leaving behind a patterned photoresist layer on the oxide layer. The oxide layer on the first side 101 of the silicon substrate 100 may be then etched using a chemical or plasma process (e.g., plasma etching using CHF₃ gas, plasma etching using CF₄ gas), which may remove the oxide layer in the areas not covered by the photoresist layer. The remaining photoresist layer may be removed using a solvent or other method (such as oxygen (O₂) dry etch), leaving behind the oxide mask 102 (e.g., a patterned silicon oxide mask) on the first side 101 of the silicon substrate 100.

FIG. 1B illustrates a beam structure 110 formed by etching (e.g., anisotropic etching) the first side 101 of the silicon substrate 100. The beam structure 110 protruding from the first side 101 of the silicon substrate 100 may be formed using alternating cycles of two different types of fabrication operations: an etching operation (e.g., a high-rate etching operation) and a deposition operation (e.g., a passivating operation). The etching and deposition operations may be repeated several times. Each time the etching and deposition operation is performed the beam structure 110 is elongated (protruding from the silicon substrate 100). As illustrated, the beam structure 110 may include a first notch 112a, 112b, which may be adjacent to the oxide mask 102, a second notch 114a, 114b, and a body 111 between the first notch 112a, 112b and the second notch 114a, 114b. A first width (W1) of the first notch 112a, 112b may be equal to or similar to the second width (W2) of the second notch 114a, 114b. However, in some circumstances, the first width (W1) of the first notch 112a, 112b may be greater than the second width (W2) of the second notch 114a, 114b. Alternatively, the second width (W2) of the second notch 114a, 114b may be greater than the first width (W1) of the first notch 112a, 112b. A third width (W3) of the body 111 is also illustrated and may be greater than the first width (W1) of the first notch 112a, 112b and the second width (W2) of the second notch 114a, 114b. The body 111 may comprise the area between the first notch 112a, 112b and the second notch 114a, 114b.

The first notch 112a, 112b may be used to allow an oxide layer 122a, 122b, 122c, 122d (shown in FIG. 1C) to better protect the beam structure 110 (e.g., top corner edges 110a, 110b of the beam structure 110) during a subsequent isotropic etching process (shown in FIG. 1E). The second notch 114a, 114b may be used to narrow the width of the lower portion of the beam structure 110 (e.g., second width W2) so a less aggressive isotropic etching process may be used when releasing the beam structure 110 from the silicon substrate 100 (as shown in FIG. 1E).

The etching operation may include exposing the silicon substrate 100 to a plasma of reactive gases (e.g., SF₆ gas) that may etch away the material (e.g., polymer material deposited in the deposition operation, or material from the silicon substrate 100) in the areas not covered by the patterned oxide mask 102. The deposition operation may also include exposing the silicon substrate 100 to a plasma of a different type of gas (e.g., C₄F₈ gas), which may deposit a thin layer of polymer material on the surface, which may effectively stop the etching process. For example, each alternating cycle may last for 2 to 4 seconds.

The first notch 112a, 112b may be formed by extending the etching operation to 7˜10 seconds. As a result of this process, a significantly greater amount of material may be etched from the silicon substrate 100. Turning back to the figures, the surface of first notch 112a, 112b is shown as recessed in both a vertical direction and a horizontal direction. The first notch 112a, 112b may be near the top corner edges 110a, 110b. Similarly, the second notch 114a, 114b may be formed by extending the time of the etching operation to 7˜10 seconds. When the time of the etching operation is increased, a significantly greater amount of material may be etched from the silicon substrate 100. The additional etching may result in the surface of second notch 114a, 114b being recessed in vertical and horizontal directions as shown. The second notch 114a, 114b may be near the bottom corner edges 110c, 110d.

FIG. 1C illustrates the beam structure 110 extending from a surface (e.g., a first side 101) of the silicon substrate 100. An oxide mask 102 may be positioned on a portion of the beam structure 110 that is opposite the portion of the beam structure 110 that engages the silicon substrate 100. As illustrated, the silicon substrate 100 may have a beam structure 110 extending from the surface of the silicon substrate 100. A second notch 114a, 114b may be adjacent the silicon substrate 100 followed by a body 111 of the beam structure 110, a first notch 112c, 112d, and the oxide mask 102. An oxide layer 122a, 122b, 122c, 122d (e.g., a silicon dioxide layer) may be positioned about the oxide mask 102 and the beam structure 110, and may form an upper layer on the silicon substrate 100. The oxide layer 122a, 122b, 122c, 122d may be deposited on the silicon substrate 100 using a suitable technique. For example, a tetraethyl orthosilicate (TEOS) process may be used with a radio frequency (RF) power source to form the “conformal” oxide layer 122c on the silicon substrate 100. During the TEOS process, the silicon substrate 100 may be placed in a chemical vapor deposition (CVD) reactor chamber. Under a vacuum condition, the silicon substrate 100 may be heated to a certain temperature (e.g., temperature between 350° C. and 450° C. such as 400° C.) and a mixture gas of the TEOS and oxygen may be introduced into the chamber. As a result, the oxide layer 122a, 122b, 122c, 122d (e.g., silicon dioxide layer) may be formed on the silicon substrate 100, the oxide mask 102, and the beam structure 110.

FIG. 1D illustrates the beam structure 110 extending from the silicon substrate 100, the oxide mask 102 positioned on the beam structure 110, and an oxide layer 122a, 122b, 122c, 122d (e.g., silicon dioxide layer) deposited on the side surfaces of the oxide mask 102 and the beam structure 110. The portion of the oxide layer 122a, 122b, 122c, 122d (e.g., silicon dioxide layer) on a top surface (e.g., horizontal surface) of the oxide mask 102 (e.g., oxide layer 122a) and a top surface (e.g., horizontal surface) of the silicon substrate 100 (e.g., oxide layer 122c) may be removed using a suitable technique. For example, the portions of the top surfaces of the oxide layer 122a, 122b, 122c, 122d (e.g., oxide layer 122a and oxide layer 122c) may be removed using a suitable anisotropic etching process or the same or a similar process described in the etching operation above (e.g., etching operation using the plasma of reactive gases).

FIG. 1E illustrates a first mechanical beam 130, which may comprise, for example, the beam structure 110 and the oxide mask 102 with the oxide layer 122b, 122d (e.g., silicon dioxide layer) on the side surfaces of the beam structure 110 and the oxide mask 102, which may be detached or released from the silicon substrate 100 using a suitable technique. For example, the first mechanical beam 130 may be detached or released from the silicon substrate 100 by a first etching process (e.g., an isotropic etching process) using sulfur hexafluoride (SF₆) gas and inductive-coupled RF power in a vacuum chamber. In some circumstances, xenon difluoride (XeF₂) may be used for the first etching process. During the first etching process, the SF₆ gas may be introduced into the chamber containing the silicon substrate 100 to be etched, and a high-frequency RF power source may be used to generate an electromagnetic field in the chamber. The RF power source may be coupled to an inductive coil, which may generate a magnetic field that in turn may induce an electric field in the gas. This electric field may ionize the gas, creating a plasma. The first etching process may occur when the energetic ions and radicals in the plasma react with the surface of the silicon substrate 100, which may remove material in a selective manner. In this example, the plasma may perform an isotropic etching on the silicon substrate 100. As a result, the first mechanical beam 130 may be released or detached from the silicon substrate 100. As shown, the reduced width (W2) of the beam structure 110 may allow the use of a less aggressive etching process to release the first mechanical beam 130 from the silicon substrate 100. In other words, an amount of undercut to release the first mechanical beam 130 may be reduced because of the second notch 114a, 114b.

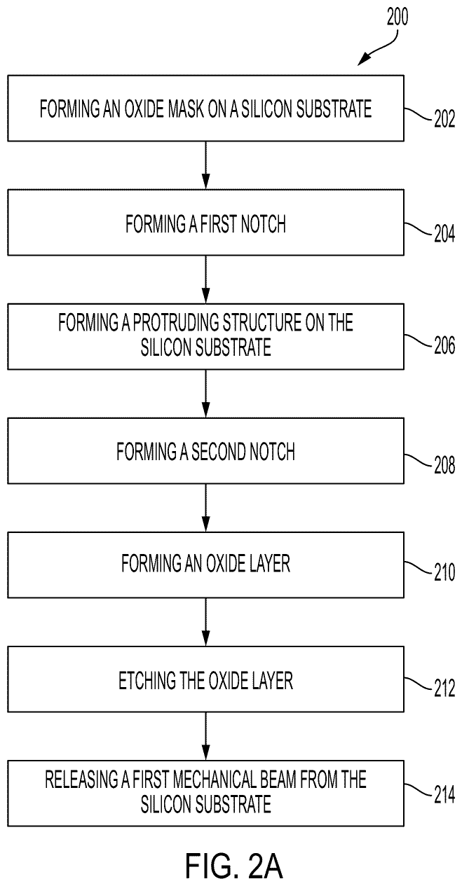

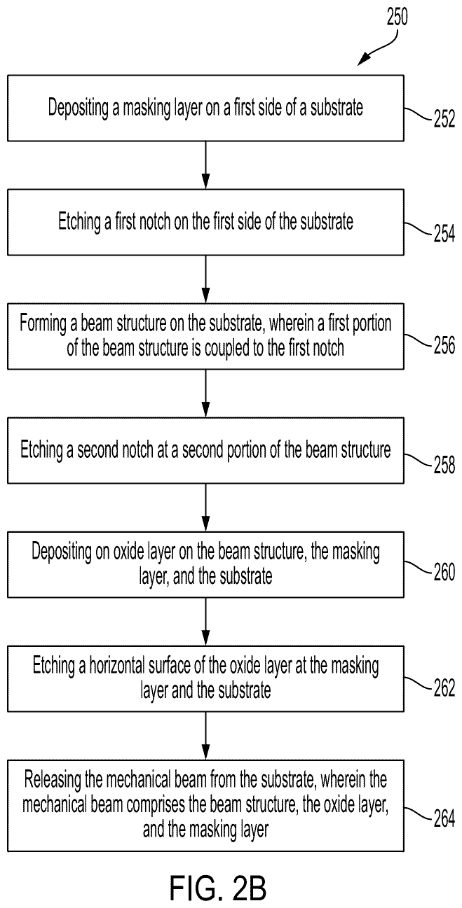

FIG. 2A illustrates a flowchart of an example arrangement of operations for a method 200 of generating or fabricating the first mechanical beam 130 in accordance with the disclosure.

The method 200, at operation 202, may include forming an oxide mask 102 on the silicon substrate 100. As discussed above, the deposition process and photolithography process may be used to form the oxide mask 102 on the silicon substrate 100. The oxide mask may be any suitable oxide mask such as a silicon oxide mask. A silicon oxide mask may comprise one or more of silicon dioxide, silicon carbide, or the like.

The method 200, at operation 204, includes forming or creating a first notch 112a, 112b by performing a first relatively aggressive etching operation as shown in FIG. 1B. The relatively aggressive etching operation may be an etching operation in which the etching time and/or temperature is higher when compared to an etching time and/or temperature for other etching operations used in the method 200. The etching time for the relatively aggressive etching operation may be between about 7 and about 10 seconds which may be compared to an etching operation time between about 2 seconds and about 4 seconds for other etching operations used in the method 200. The temperature range for aggressive etching and other etching operations are the same. The electrode temperature can be from 5° Celsius to 15° Celsius, more preferably 10° Celsius.

The method 200, at operation 206, includes forming a protruding structure on the silicon substrate. The protruding structure may be a beam structure 110 that may be formed using an anisotropic etching process. As discussed, the beam structure 110 may be formed by performing alternating cycles of two different types of fabrication operation: an etching operation (e.g., high-rate etching operation) and deposition operation (e.g., passivating operation) on the silicon substrate 100.

The method 200, at operation 208, includes forming or creating a second notch 114a, 114b by performing a second relatively aggressive etching step as shown in FIG. 1B. As shown, after forming the beam structure 110 at a desired height, the second notch 114a, 114b may be formed at the lower portion of the beam structure 110. As discussed, the relatively aggressive etching operation may be an etching operation in which the etching time and/or temperature is higher when compared to an etching time and/or temperature for other etching operations used in the method 200. The etching time for the relatively aggressive etching operation may be between about 7 and about 10 seconds which may be compared to an etching operation time between about 2 seconds and about 4 seconds for other etching operations used in the method 200.

The method 200, at operation 210, includes forming an oxide layer on the oxide mask 102, the beam structure 110, and the silicon substrate 100 as shown in FIG. 1C.

The method 200, at operation 212, includes etching the top surfaces (e.g., horizontal surfaces) of the oxide layer 122 as shown in FIG. 1D.

The method 200, at operation 214, includes releasing a first mechanical beam 130 from the silicon substrate 100. As discussed, isotropic etching may be used to release the first mechanical beam 130 from the silicon substrate 100.

As a result, the height and stiffness of the multiple first mechanical beams 130 may be more uniform by forming the second notch 114a, 114b during the production process which may allow the use of a less aggressive etching process (with less process variation). This may stabilize the yield.

FIG. 2B illustrates a flowchart of an example arrangement of operations for a method 250 of generating or fabricating the first mechanical beam 130 in accordance with the disclosure. The method 250 may include depositing a masking layer (e.g., an oxide mask 102, as illustrated in FIGS. 1A-1E, such as a silicon oxide mask) on a first side of a substrate (e.g., a silicon wafer), as shown at operation 252. The method 250 may include etching a first notch (e.g., first notch 112 as illustrated in FIGS. 1B-1E) on the first side of the substrate (e.g., a silicon wafer), as shown at operation 254. The method 250 may include forming a beam structure (e.g., beam structure 110 as illustrated in FIGS. 1B-1E) on the substrate (e.g., a silicon wafer) in which a first portion of the beam structure (e.g., beam structure 110 as illustrated in FIGS. 1B-1E) is coupled to the first notch (e.g., first notch 112 as illustrated in FIGS. 1B-1E), as shown at operation 256.

The method 250 may include etching a second notch (e.g., second notch 114 as illustrated in FIGS. 1B-1D) at a second portion of the beam structure (e.g., beam structure 110 as illustrated in FIGS. 1B-1E), as shown at operation 258. The method 250 may include depositing an oxide layer (e.g., oxide layer 122 as illustrated in FIGS. 1C-1E) on the beam structure (e.g., beam structure 110 as illustrated in FIGS. 1B-1E), the masking layer (e.g., an oxide mask 102, as illustrated in FIGS. 1A-1E, such as a silicon oxide mask), and the substrate (e.g., a silicon wafer), as shown at operation 260. The method 250 may include etching a horizontal surface of the oxide layer (e.g., oxide layer 122 as illustrated in FIGS. 1C-1E) at the masking layer (e.g., an oxide mask 102, as illustrated in FIGS. 1A-1E, such as a silicon oxide mask) and the substrate (e.g., a silicon wafer), as shown at operation 262.

The method may include releasing the mechanical beam (e.g., mechanical beam 130 as illustrated in FIG. 1E) from the substrate (e.g., a silicon wafer) in which the mechanical beam (e.g., mechanical beam 130 as illustrated in FIG. 1E) comprises the beam structure (e.g., beam structure 110 as illustrated in FIGS. 1B-1E), the oxide layer (e.g., oxide layer 122 as illustrated in FIGS. 1C-1E), and the masking layer (e.g., an oxide mask 102, as illustrated in FIGS. 1A-1E, such as a silicon oxide mask), as shown at operation 264.

### II. Method for Reducing Variability of a Mechanical Beam

Reducing the amount of undercut of a silicon structure (e.g., beam structure 110 as illustrated in FIGS. 1B-1E) may facilitate increased control over the dimensions of the mechanical beam (e.g., mechanical beam 130 as illustrated in FIG. 1E). By increasing control over the dimensions of the mechanical beam (e.g., mechanical beam 130 as illustrated in FIG. 1E), the mechanical behavior of the mechanical beam may be more similar to the modeled behavior of the mechanical beam when compared to a case in which the amount of undercut of the silicon structure (e.g., beam structure 110 as illustrated in FIGS. 1B-1E) is not reduced. Consequently, there may be reduced variability in performance between different devices that use the mechanical beam (e.g., mechanical beam 130 as illustrated in FIG. 1E).

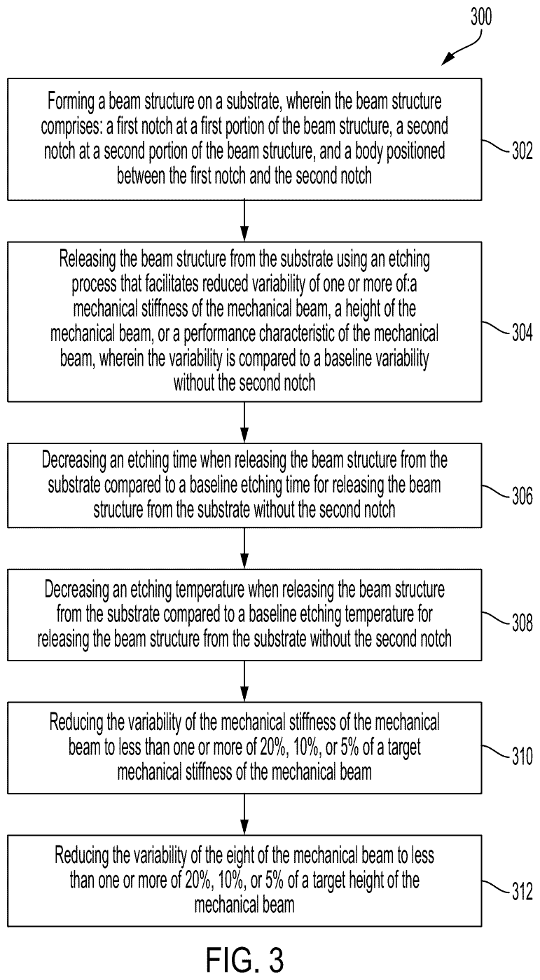

As illustrated in FIG. 3, a method 300 for reducing variability of a mechanical beam (e.g., mechanical beam 130 as illustrated in FIG. 1E) in a microelectromechanical (MEM) device may include forming a beam structure (e.g., beam structure 110 as illustrated in FIGS. 1B-1E) on a substrate (e.g., a silicon wafer), as shown in operation 302. The beam structure (e.g., beam structure 110 as illustrated in FIGS. 1B-1E) may be formed using alternating cycles of deposition and etching.

The beam structure (e.g., beam structure 110 as illustrated in FIGS. 1B-1E) may include a first notch (e.g., first notch 112 as illustrated in FIGS. 1B-1E) at a first portion (e.g., an upper portion) of the beam structure, a second notch (e.g., second notch 114 as illustrated in FIGS. 1B-1D) at a second portion (e.g., a lower portion) of the beam structure, and a body (e.g., body 111 as illustrated in FIGS. 1B-1E) positioned between the first notch and the second notch.

The inclusion of the first notch (e.g., first notch 112 as illustrated in FIGS. 1B-1E) may facilitate better protection of the top corner edges (e.g., top corner edges 110a, 110b, as illustrated in FIGS. 1B-1E) of the beam structure (e.g., beam structure 110 as illustrated in FIGS. 1B-1E) during an isotropic release etch (e.g., as illustrated in FIG. 1E). The first notch may be formed before the alternating cycles of deposition and etching by using a relatively aggressive etching operation.

The inclusion of the second notch (e.g., second notch 114 as illustrated in FIGS. 1B-1D) may reduce the undercut of the silicon structure (e.g., beam structure 110 as illustrated in FIGS. 1B-1E) because the bottom of the mechanical beam (e.g., mechanical beam 130 as illustrated in FIG. 1E) may be pinched off. Alternatively or in addition, the second notch may facilitate better protection of the bottom corner edges (e.g., bottom corner edges 110c, 110d, as illustrated in FIGS. 1B-1E) of the beam structure (e.g., beam structure 110 as illustrated in FIGS. 1B-1E) during an isotropic release etch (e.g., as illustrated in FIG. 1E). The second notch may be formed after the alternating cycles of deposition and etching by using a relatively aggressive etching operation.

The method 300 may include releasing the beam structure (e.g., beam structure 110 as illustrated in FIGS. 1B-1E) from the substrate (e.g., a silicon wafer) using an etching process that may facilitate reduced variability of one or more of: a mechanical stiffness of the mechanical beam (e.g., mechanical beam 130 as illustrated in FIG. 1E), a height of the mechanical beam, or a performance characteristic of the mechanical beam, as shown in operation 304. The variability may be compared to a baseline variability without the second notch (e.g., second notch 114 as illustrated in FIGS. 1B-1E). The etching process used to release the beam structure from the substrate may be an isotropic silicon etch (e.g., using SF₆ or XeF₂).

The inclusion of the second notch may facilitate a less aggressive isotropic release etch with respect to time and/or temperature of the release etch. The method may include decreasing an etching time when releasing the beam structure (e.g., beam structure 110 as illustrated in FIGS. 1B-1E) from the substrate (e.g., a silicon wafer) compared to a baseline etching time for releasing the beam structure from the substrate without the second notch, as shown in operation 306. The method may include decreasing an etching temperature when releasing the beam structure (e.g., beam structure 110 as illustrated in FIGS. 1B-1E) from the substrate compared to a baseline etching temperature for releasing the beam structure from the substrate without the second notch, as shown in operation 308.

The inclusion of the first notch 112a, 112b and the second notch 114a, 114b may facilitate increased uniformity for the mechanical stiffness of the mechanical beam after the release of the beam structure 110 from the substrate. The mechanical beam may be stiffer when the mechanical beam has a greater height. Therefore, controlling the height of the mechanical beam may facilitate control over the stiffness of the mechanical beam. The method may include reducing the variability of the mechanical stiffness of the mechanical beam to less than one or more of 20%, 10%, or 5% of a target mechanical stiffness of the mechanical beam, as shown in operation 310. The method may include reducing the variability of the height of the mechanical beam to less than one or more of 20%, 10%, or 5% of a target height of the mechanical beam, as shown in operation 312.

The method may include reducing the variability of a performance characteristic of the mechanical beam to less than one or more of 20%, 10%, 5% or a target performance characteristic of the mechanical beam. The performance characteristic may be one or more of micro electro-mechanical system response to its predicted position when actuated.

III. Comparison between Single Notch Etch Device and Double Notch Etch Device

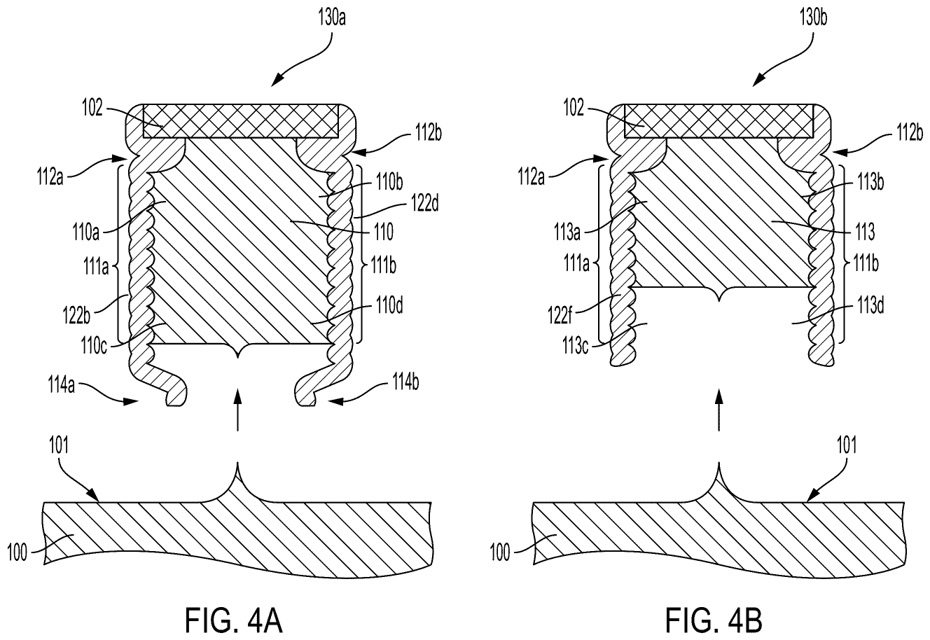

As illustrated in the cross-section of FIGS. 4A-B, the inclusion of a second notch 114a, 114b may facilitate the release of a beam structure 110. The height should impact the release process. A narrower beam at the bottom at the second notch 114a, 114b would make it easier to release the beam 110. A second mechanical beam 130b including a second beam structure 113 may be released from the silicon substrate 100 by a second etching process (e.g., isotropic etching process). The second beam structure 113 may include a first notch 112a, 112b but may not include the second notch 114a, 114b. The first mechanical beam 130a may be released from the silicon substrate 100 by the first etching process (e.g., isotropic etching process) for comparison. Except for the presence of the second notch 114a, 114b and oxide layer on the second notch 114a, 114b, the first mechanical beam 130a and the second mechanical beam 130b may be the same or similar before release from the silicon substrate 100 in this example.

Due to the existence of the second notch 114a, 114b on the beam structure 110 of the first mechanical beam 130a, a less aggressive etching process (e.g., less aggressive isotropic etching process) may be used when releasing or detaching the first mechanical beam 130a from the silicon substrate 100 than when releasing or detaching the second mechanical beam 130b from the silicon substrate 100, as shown in FIGS. 4A-B. In other words, the second etching process may be more aggressive when manufacturing the second mechanical beam 130b than the first etching process used to manufacture the first mechanical beam 130a, and the second etching process used for the second mechanical beam 130b may undercut the second beam structure 113 in a greater amount than the first etching process undercuts the beam structure 110.

As the etching process becomes more aggressive, there is a greater chance of variation in the etching process. For example, the bottom corner edges 110c, 110d may be maintained in a greater amount when the first etching process is used to manufacture the first mechanical beam 130a when compared to the corners 113c, 113d when the second etching process is used to manufacture the second mechanical beam 130b. The corners 110a, 110b may be maintained in a greater amount when the first etching process is used to manufacture the first mechanical beam 130a when compared to the corners 113a, 113b when the second etching process is used to manufacture the second mechanical beam 130b. In addition or alternatively, the height of the first beam structure 110 (e.g., as shown by first body 111a) may be greater than the height of the second beam structure 113 (e.g., as shown by second body 111b). Because the height may be maintained to a greater extent when manufacturing the first beam structure 110, there may be less variation in the height because less unknown etching occurs. In addition or alternatively, the height of the first body 111a may be greater than the height of the second body 111b.

After detaching the mechanical beam 130a, 130b from the silicon substrate 100, a first height of the beam structure 110 of the first mechanical beam 130a may be greater than a second height of the second beam structure 113 of the second mechanical beam 130b. Also, the second height of the second mechanical beam 130b can be significantly shorter and less stiff than expected due to the greater process variation in the second etching process. In contrast, the first height of the first mechanical beam 130a may be closer to the height as expected due to less process variation in the first etching process. Also, as shown, the second mechanical beam 130b may have an oxide layer 122f that may continue past the corners 113c, 113d to a greater extent when compared to the oxide layer 122b, 122d of the first mechanical beam 130a.

Since the first etching process is less aggressive than the second etching process, the first etching process may be better controlled (e.g., more uniformly controlled). As a result, there may be less variation in mechanical beam 130a resulting from the first etching process than the mechanical beam 130b resulting from the second etching process. Therefore, multiple first mechanical beams 130a (using the beam structures 110 with the first notch 112a, 112b and second notch 114a, 114b during the fabrication) may be produced with reduced height variations between the various mechanical beams. This also means that the mechanical beams produced may have reduced stiffness variations because the mechanical stiffness of the mechanical beam may be directly related to the height of the mechanical beam. For example, the mechanical stiffness of the mechanical beam may decrease when the height of the mechanical beam becomes shorter. For another example, the mechanical stiffness of the mechanical beam may increase when the height of the mechanical beam becomes greater.

### IV. Double Notch Etch Device

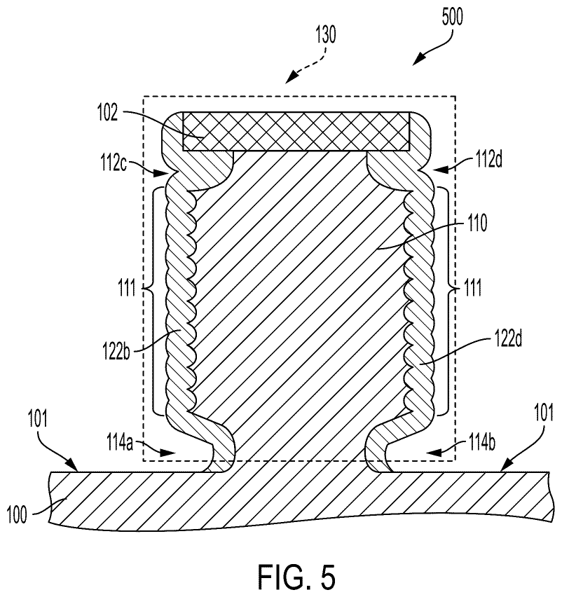

A device having a double notch etch may facilitate uniformity in manufacture. As illustrated in FIG. 5, a microelectromechanical (MEM) device 500 may include a substrate (e.g., a silicon substrate 100 such as a silicon wafer) and a mechanical beam 130. The mechanical beam 130 may include a beam structure 110. The beam structure 110 may be positioned on a first side 101 of the silicon substrate 100. A first portion (e.g., an upper portion) of the beam structure may include a first notch 112c, 112d and a second portion (e.g., a lower portion) of the beam structure may include a second notch 114a, 114b. The mechanical beam 130 may include a masking layer (e.g., an oxide mask 102 such as a silicon oxide mask) positioned on a horizontal surface of the beam structure 110. The mechanical beam 130 may include an oxide layer 122b, 122d positioned on a vertical surface of the beam structure 110. The oxide layer 122b, 122d may be a silicon dioxide layer.

The second notch 114a, 114b may be recessed in a vertical direction and a horizontal direction. By recessing the second notch 114a, 114b in a vertical direction and a horizontal direction, reduced undercut of the beam structure 110 may occur when an isotropic release etch is used to release the mechanical beam 130 from the (e.g., a silicon substrate 100 such as a silicon wafer). Alternatively or in addition, the second notch 114a, 114b may have a second width at the second portion of the beam structure 110 that is less than a body width of a body 111 of the beam structure 110.

The second notch 114a, 114b may be operable to reduce a variability of one or more of: a mechanical stiffness of the mechanical beam 130, a height of the mechanical beam 130, or a performance characteristic of the mechanical beam 130. The variability may be measured after an isotropic release etch. The variability may be compared to a baseline variability without the inclusion of the second notch on the beam structure 110. The variability of the height of the mechanical beam may be reduced to less than one or more of 20%, 10%, or 5% of a target height of the mechanical beam 130.

The first width of the first notch 112c, 112d may be recessed in a vertical direction and a horizontal direction. The first notch 112c, 112d may be operable to increase a protection of one or more first portion edges of the beam structure during an isotropic release etch compared to the protection of the one or more first portion edges of the beam structure during an isotropic release etch without the first notch. Alternatively or in addition, the first notch 112c, 112d may have a first width at the first portion of the beam structure 110 that is less than a body width of a body 111 of the beam structure 110.

While preferred implementations of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that any claims presented define the scope of the invention and that methods and structures within the scope of these claims and their equivalents be covered thereby.

What is claimed:

1. A microelectromechanical (MEM) device comprising:
a substrate; and
a mechanical beam comprising
a beam structure on a first side of the substrate, wherein a first portion of the beam structure comprises a first notch and a second portion of the beam structure comprises a second notch,
a masking layer positioned on a horizontal surface of the beam structure, and
an oxide layer positioned on a vertical surface of the beam structure.

2. The MEM device of claim 1 wherein the second notch is operable to reduce a variability of one or more of:
a mechanical stiffness of the mechanical beam,
a height of the mechanical beam, and
a performance characteristic of the mechanical beam,
wherein the reduced variability is measured after an isotropic release etch, and wherein the variability is compared to a baseline variability without the second notch.

3. The MEM device of claim 2 wherein the reduced height variability of the mechanical beam is reduced to less than one or more of 20%, 10%, or 5% of a target height of the mechanical beam.

4. The MEM device of claim 1 wherein:
the first notch has a first width at the first portion of the beam structure that is less than a first body width of a body of the beam structure; and
the second notch has a second width at the second portion of the beam structure that is less than a second body width of the body of the beam structure.

5. The MEM device of claim 1 wherein the first notch is operable to increase a protection of one or more first portion edges of the beam structure during an isotropic release etch compared to the protection of the one or more first portion edges of the beam structure during an isotropic release etch without the first notch.

6. The MEM device of claim 1 wherein
the first notch is recessed in a vertical direction and a horizontal direction, and
the second notch is recessed in the vertical direction and the horizontal direction.

7. The MEM device of claim 1 wherein one or more of:
the substrate comprises a silicon wafer,
the masking layer comprises an oxide mask, and
the oxide layer comprises a silicon dioxide layer.

8. A method for reducing variability of a mechanical beam in a microelectromechanical (MEM) device comprising:
forming a beam structure on a substrate, wherein the beam structure comprises
a first notch at a first portion of the beam structure,
a second notch at a second portion of the beam structure, and
a body positioned between the first notch and the second notch;
and
releasing the beam structure from the substrate using an etching process that facilitates reduced variability of one or more of
a mechanical stiffness of the mechanical beam,
a height of the mechanical beam, and
a performance characteristic of the mechanical beam,
wherein the reduced variability is compared to a baseline variability without the second notch.

9. The method of claim 8 further comprising:
decreasing an etching time when releasing the beam structure from the substrate compared to a baseline etching time for releasing the beam structure from the substrate without the second notch.

10. The method of claim 8 further comprising:
reducing the variability of the mechanical stiffness of the mechanical beam to less than one or more of 20%, 10%, or 5% of a target mechanical stiffness of the mechanical beam.

11. The method of claim 8 further comprising:
reducing the variability of the height of the mechanical beam to less than one or more of 20%, 10%, or 5% of a target height of the mechanical beam.

12. The method of claim 8 wherein the performance characteristic comprises one or more of micro electro-mechanical system response to a predicted position when actuated.

13. A method for fabricating a mechanical beam in a microelectromechanical (MEM) device comprising:
depositing a masking layer on a first side of a substrate;
etching a first notch on the first side of the substrate;
forming a beam structure on the substrate, wherein a first portion of the beam structure is coupled to the first notch;
etching a second notch at a second portion of the beam structure;
depositing an oxide layer on the beam structure, the masking layer, and the substrate;
etching a horizontal surface of the oxide layer at the masking layer and the substrate; and
releasing the mechanical beam from the substrate, wherein the mechanical beam comprises the beam structure, the oxide layer, and the masking layer.

14. The method of claim 14 wherein the substrate comprises a silicon wafer.

15. The method of claim 14 wherein the masking layer comprises an oxide mask.

16. The method of claim 14 wherein the oxide layer comprises a silicon dioxide layer.

17. The method of claim 14 wherein the first portion of the beam structure is an upper portion of the beam structure and the second portion of the beam structure is a lower portion of the beam structure.

18. The method of claim 14 wherein one or more of the first notch or the second notch is etched by increasing an etching time compared to a body etching time for a body of the beam structure.
